(19) United States
(12) Patent Application Publication
(10) Pub. No.: US 2026/0090121 A1
(43) Pub. Date: Mar. 26, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Bing Cheng You, Taichung City (TW); Feng-Chi Hung, Chu-Bei City (TW); Wei Long Chen, New Taipei City (TW); Chih Cheng Shih, Kaohsiung City (TW); Jen-Cheng Liu, Hsin-Chu City (TW)

(21) Appl. No.: 18/981,788

(22) Filed: Dec. 16, 2024

Related U.S. Application Data
(60) Provisional application No. 63/698,146, filed on Sep. 24, 2024.

(51) Int. Cl. H10F 39/00; H10F 39/18

(52) U.S. Cl. CPC H10F 39/807; H10F 39/014; H10F 39/182

(57) ABSTRACT

The present disclosure, in some embodiments, relates to an integrated chip. The integrated chip includes a substrate having a device region with one or more semiconductor devices. The substrate has one or more interior surfaces that form one or more trenches within the substrate along opposing sides of the device region. A multi-layer film stack is disposed along the one or more interior surfaces of the substrate. A core material is arranged within the one or more trenches and is surrounded by the multi-layer film stack. The multi-layer film stack includes a plurality of dielectric material respectively having different electron affinities. The plurality of dielectric materials are arranged to form one or more potential wells within the multi-layer film stack.

### REFERENCE TO RELATED APPLICATION

This application claims the benefit of U.S. Provisional Application No. 63/698,146, filed on Sep. 24, 2024, the contents of which are incorporated herein by reference in their entirety.

### BACKGROUND

Integrated circuits (IC) with image sensors are used in a wide range of modern-day electronic devices, such as cameras and cell phones, for example. In recent years, complementary metal-oxide semiconductor (CMOS) image sensors have begun to see widespread use, largely replacing charge-coupled device (CCD) image sensors. Compared to CCD image sensors, CMOS image sensors are increasingly favored due to low power consumption, a small size, fast data processing, a direct output of data, and low manufacturing cost. Some types of CMOS image sensors include front-side illuminated (FSI) image sensors and back-side illuminated (BSI) image sensors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate some embodiments of an integrated chip comprising a trench isolation structure having a multi-layer film stack that forms a potential well configured to trap charge carriers.

FIGS. 2A-2B illustrate some additional embodiments of an integrated chip comprising a trench isolation structure having a multi-layer film stack that forms a potential well configured to trap charge carriers.

FIG. 3A illustrates some additional embodiments of an integrated chip comprising a trench isolation structure having a multi-layer film stack that forms one or more potential wells configured to trap charge carriers.

FIGS. 3B-3C illustrate some embodiments of exemplary energy band diagrams corresponding to a disclosed multi-layer film stack.

FIGS. 4A-4B illustrate cross-sectional views of some additional embodiments of integrated chips comprising a trench isolation structure having a disclosed multi-layer film stack.

FIGS. 5A-5B illustrate some embodiments of an image sensor integrated chip comprising a trench isolation structure having a disclosed multi-layer film stack.

FIG. 6 illustrates some additional embodiments of an image sensor integrated chip comprising a trench isolation structure having a disclosed multi-layer film stack.

FIGS. 7A-7B illustrate some embodiments of an image sensor integrated chip comprising a trench isolation structure having a disclosed multi-layer film stack.

FIGS. 8-11 illustrate cross-sectional views of some additional embodiments of image sensor integrated chips comprising a trench isolation structure having a disclosed multi-layer film stack.

FIGS. 12-26 illustrate cross-sectional views of some embodiments of a method of forming an integrated chip comprising a trench isolation structure having a multi-layer film stack that forms a potential well configured to trap charge carriers.

FIG. 27 illustrates a flow diagram of some embodiments of a method of forming an integrated chip comprising a trench isolation structure having a multi-layer film stack that forms a potential well configured to trap charge carriers.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Many electronic devices (e.g., cameras, cellular telephones, computers, etc.) include one or more image sensor integrated chips (ICs) including image sensing elements configured to capture images. An image sensor IC may contain a large array of pixel regions respectively including an image sensing element disposed within a semiconductor substrate. The pixel regions are often electrically isolated from one another by trench isolation structures (e.g., deep trench isolation structures). The trench isolation structures may comprise an insulating material disposed within a trench in the semiconductor substrate.

During fabrication of a trench isolation structure, a semiconductor substrate may be etched to form a trench that is subsequently filled with one or more dielectric materials. The etching processes used to form the trench can damage the semiconductor substrate, resulting in defects (e.g., dangling bonds, etc.) along interior surfaces of the semiconductor substrate forming the trench. The defects may trap electrons and cause an unwanted leakage current to flow between adjacent pixel regions, leading to dark current and/or white pixel issues within the image sensor IC.

Some trench isolation structures may include a high-k dielectric material disposed along the interior surfaces of the semiconductor substrate forming the trench. The high-k dielectric material stores charges, which are able to generate an electric field that accumulate holes along the interior surfaces of the semiconductor substrate. The accumulated holes are configured to passivate the defects, thereby reducing dark current and/or white pixel issues. However, it has been appreciated that the electric field provided by such high-k dielectric materials may not be strong enough to achieve a sufficient hole density to effectively passivate the electrons trapped in the defects. Therefore, an image sensor IC having a high-k dielectric material along sidewalls of a trench formed during fabrication of a trench isolation structure may still suffer from performance degradation due to dark current and/or white pixel issues.

The present disclosure relates to an integrated chip comprising a trench isolation structure having a multi-layer film stack that forms a potential well configured to trap charge carriers. In some embodiments, the integrated chip includes a substrate having a device region with one or more semiconductor devices (e.g., one or more image sensing elements). The substrate has one or more interior surfaces that form one or more trenches within the substrate along opposing sides of the device region. A trench isolation structure is arranged within the one or more trenches. The trench isolation structure includes a multi-layer film stack and a core material. The multi-layer film stack is disposed within the one or more trenches and along the one or more interior surfaces of the substrate. The multi-layer film stack comprises a plurality of dielectric materials respectively having different electron affinities. The plurality of dielectric materials are arranged to form one or more potential wells within the multi-layer film stack. The potential wells are able to trap charge carriers (e.g., electrons). By trapping charge carriers, the multi-layer film stack is able to increase a total charge associated with the isolation structure and generate an electric field that attracts opposite charge carriers (e.g., holes) towards the one or more interior surfaces of the substrate. The opposite charge carriers are able to passivate defects (e.g., traps) along the one or more interior surfaces of the substrate, thereby reducing unwanted current (e.g., dark current, leakage current, etc.) and improving performance of the integrated chip.

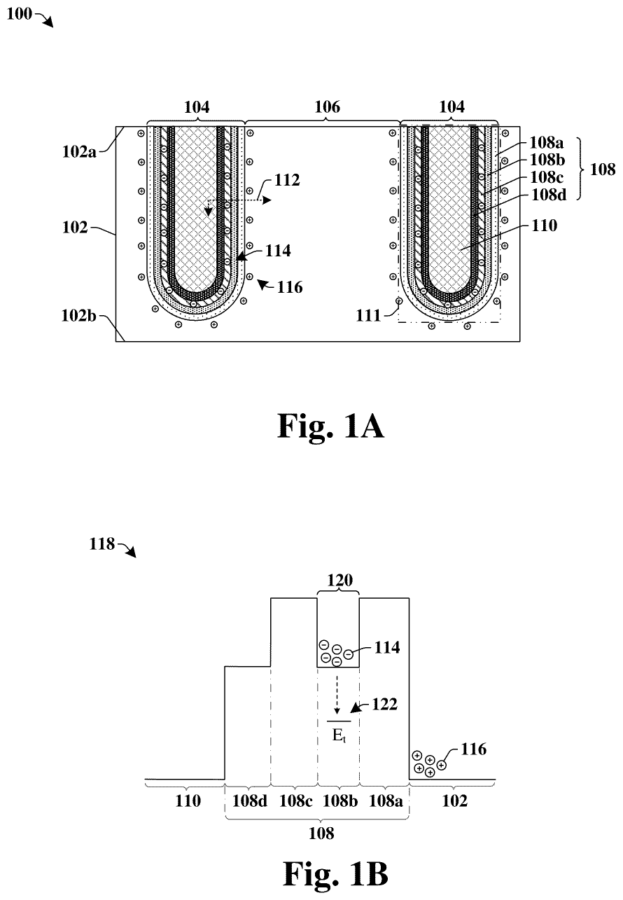

FIG. 1A illustrates a cross-sectional view of some embodiments of an integrated chip 100 comprising a trench isolation structure having a multi-layer film stack that forms a potential well configured to trap charge carriers.

The integrated chip 100 comprises a substrate 102 having a first side 102a and a second side 102b opposing the first side 102a. The substrate 102 comprises a device region 106 having a semiconductor device. In some embodiments, the semiconductor device may comprise and/or be a transistor device, such as a planar FET, a FinFET, a gate all around structure, a nanowire structure, a high voltage device, and/or the like. In other embodiments, the semiconductor device may comprise or be an image sensing element configured to convert incident radiation to an electrical signal. In some embodiments, the image sensing element may comprise a photodiode (e.g., a PN photodiode, a PIN photodiode, a Schottky photodiode, an avalanche photodiode, etc.).

The substrate 102 comprises one or more interior surfaces (e.g., sidewalls) that form one or more trenches 104 arranged along opposing sides of the device region 106. The one or more trenches 104 extend from the first side 102a of the substrate 102 to within the substrate 102. A trench isolation structure 111 is arranged within the one or more trenches 104. The trench isolation structure 111 comprises a multi-layer film stack 108 and a core material 110. The multi-layer film stack 108 is arranged along the one or more interior surfaces of the substrate 102. The multi-layer film stack 108 separates the core material 110 from the substrate 102. In some embodiments, the multi-layer film stack 108 extends along opposing sidewalls and a bottom of the core material 110.

The multi-layer film stack 108 comprises a plurality of dielectric materials 108a-108d stacked onto one another. In some embodiments, the multi-layer film stack 108 may comprise a first dielectric material 108a, a second dielectric material 108b stacked onto the first dielectric material 108a, a third dielectric material 108c stacked onto the second dielectric material 108b, and a fourth dielectric material 108d stacked onto the third dielectric material 108c. In some additional embodiments, the multi-layer film stack 108 may comprise one or more additional dielectric materials. Two or more of the plurality of dielectric materials 108a-108d have different electron affinities. The plurality of dielectric materials 108a-108d are arranged to give the multi-layer film stack 108 a conduction energy band having one or more potential wells (e.g., one potential well, two potential wells, three potential wells, etc.). In some embodiments, the conductive energy band of the multi-layer film stack 108 is symmetric. In some embodiments, the conductive energy band of the multi-layer film stack 108 is asymmetric.

FIG. 1B illustrates an exemplary energy band diagram 118 associated with a disclosed multi-layer film stack 108. The exemplary energy band diagram 118 is taken along line 112 of FIG. 1A.

As can be seen in the energy band diagram 118, the plurality of dielectric materials 108a-108d of the multi-layer film stack 108 have different conduction band energies. The different conduction band energies form a potential well 120 within one of the dielectric materials of the multi-layer film stack 108. The potential well 120 is able to trap charge carriers (e.g., electrons 114 or holes) within the multi-layer film stack 108. The trapped charge carriers increase a total charge associated with the trench isolation structure (e.g., 111 of FIG. 1A) and generate an electric field, which attracts opposite charge carriers (e.g., holes 116 or electrons) towards the one or more interior surfaces of the substrate 102 forming the one or more trenches 104. The opposite charge carriers within the substrate 102 can passivate defects (e.g., traps 122 configured to capture electrons within the substrate) within the substrate 102, thereby reducing unwanted current (e.g., dark current) within the substrate 102 and thus improving isolation between the device region 106 and an adjacent device region.

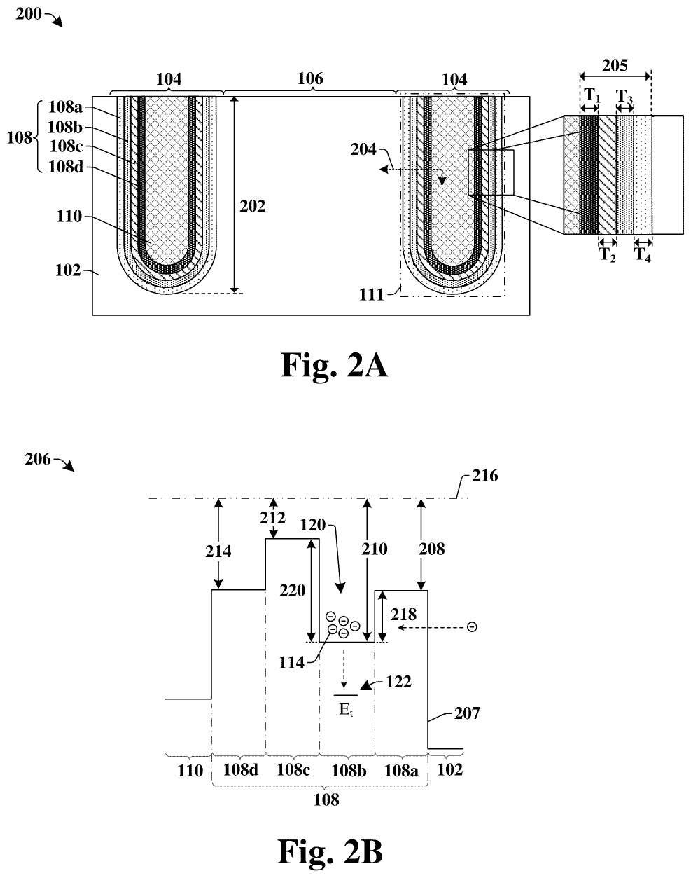

FIG. 2A illustrates a cross-sectional view of some additional embodiments of integrated chip 200 comprising a trench isolation structure having a multi-layer film stack that forms a potential well configured to trap charge carriers.

The integrated chip 200 comprises a substrate 102. The substrate 102 includes a device region 106 having a semiconductor device (e.g., a transistor device, an image sensing element, and/or the like). The substrate 102 further includes one or more interior surfaces (e.g., sidewalls) that form one or more trenches 104 along opposing sides of the device region 106. In some embodiments, the one or more trenches 104 may have a depth 202 that is in a range of between approximately 100 nanometers (nm) and approximately 10 microns, between 200 nm and approximately 5 microns, and/or other similar values.

A trench isolation structure 111 is arranged within the one or more trenches 104. The trench isolation structure 111 comprises a multi-layer film stack 108 laterally surrounding a core material 110. In some embodiments, the core material 110 may comprise a conductive material, such as aluminum, tungsten, doped polysilicon, and/or the like. In other embodiments, the core material 110 may comprise a dielectric material, such as a high-k dielectric material or a low-k dielectric material. For example, the dielectric material may comprise aluminum oxide, hafnium oxide, silicon oxide, silicon nitride, and/or the like.

The multi-layer film stack 108 comprises a plurality of dielectric materials 108a-108d stacked onto one another. For example, the multi-layer film stack 108 may comprise a first dielectric material 108a arranged on the one or more interior surfaces of the substrate 102, a second dielectric material 108b stacked onto the first dielectric material 108a, a third dielectric material 108c stacked onto the second dielectric material 108b, and a fourth dielectric material 108d stacked onto the third dielectric material 108c. In some embodiments, the multi-layer film stack 108, the core material 110, and the substrate 102 may have horizontally extending surfaces that are substantially co-planar (e.g., planar within a tolerance of a chemical mechanical planarization (CMP) process).

FIG. 2B illustrates an exemplary energy band diagram 206 associated with a disclosed multi-layer film stack 108. The exemplary energy band diagram 206 is taken along line 204 of FIG. 2A.

As shown in energy band diagram 206, the plurality of dielectric materials 108a-108d have different electron affinities 208-214 (e.g., different energy values between a conduction band energy 207 of an associated dielectric material and a vacuum energy 216). The plurality of dielectric materials 108a-108d are arranged so that the different electron affinities 208-214 form a potential well 120 within the multi-layer film stack 108. For example, in some embodiments the first dielectric material 108a may have a first electron affinity 208, the second dielectric material 108b may have a second electron affinity 210, the third dielectric material 108c may have a third electron affinity 212, and the fourth dielectric material 108d may have a fourth electron affinity 214. In some embodiments, the first electron affinity 208 and the third electron affinity 212 are less than the second electron affinity 210, so as to form the potential well 120 at a location corresponding to the second dielectric material 108b. In various embodiments, the first electron affinity 208 may be greater than, less than, or substantially equal to the third electron affinity 212. In various embodiments, the fourth electron affinity 214 may be greater than, less than, or substantially equal to the first electron affinity 208, the second electron affinity 210, and/or the third electron affinity 212.

In some embodiments, one or more treatments (e.g., thermal treatments, electrical treatments, etc.) may be applied to the multi-layer film stack 108 during fabrication of the multi-layer film stack 108. The one or more treatments cause charge carriers (e.g., electrons 114) from within the substrate 102 and/or the core material 110 to tunnel through potential energy barriers formed by the first dielectric material 108a and/or the third dielectric material 108c and into the potential well 120. The charge carriers become trapped in the potential well 120 and increase a charge of the multi-layer film stack 108. This is because once the charge carriers enter the potential well 120, the different electron affinities of the different dielectric materials form energy barriers that prevent the charge carriers from leaving the potential well 120. For example, in some embodiments, a first difference 218 between the first electron affinity 208 and the second electron affinity 210 and a second difference 220 between the second electron affinity 210 and the third electron affinity 212 may be greater than approximately 0.001 electron volts (cV), greater than approximately 0.01 eV, less than approximately 1 cV, greater than approximately 1 eV, or other similar values.

Referring again to FIG. 2A, in some embodiments the plurality of dielectric materials 108a-108d may have a total thickness 205 that is in a range of between approximately 50 nanometers (nm) and approximately 100 nm. If the total thickness 205 is less than approximately 50 nm, an amount of charges in the multi-layer film stack 108 is not enough to provide a passivation effect on defects within the substrate 102. If the total thickness 205 is greater than approximately 100 nm, a tunneling effect of charge carriers (e.g., electrons) from the substrate 102 to the potential well formed by the second dielectric material 108b will be reduced thereby reducing a passivation effect on the defects within the substrate 102. In some embodiments, the plurality of dielectric materials 108a-108d may have different thicknesses T₁-T₄. In other embodiments, the plurality of dielectric materials 108a-108d may have thicknesses T₁-T₄ that are substantially equal to one another.

In some embodiments, two or more of the plurality of dielectric materials 108a-108d may also have different oxygen densities. For example, in some embodiments the first dielectric material 108a may have a first oxygen density, the second dielectric material 108b may have a second oxygen density, the third dielectric material 108c may have a third oxygen density, and the fourth dielectric material 108d may have a fourth oxygen density. The fourth oxygen density is larger than the third oxygen density. The larger fourth oxygen density causes oxygen in the fourth dielectric material 108d to diffuse into the third dielectric material 108c and form dipoles within the third dielectric material 108c. The oxygen dipoles enhance an electric field generated by the charge carriers (e.g., electrons) trapped within the potential well and/or opposite charge carriers (e.g., holes) accumulated within the substrate 102 along the one or more interior surfaces forming the one or more trenches 104.

In some embodiments, the plurality of dielectric materials 108a-108d may respectively comprise an oxide, a nitride, a dielectric material, a high-k dielectric material, and/or the like. In some embodiments, the first dielectric material 108a may comprise one or more of zirconium oxide, hafnium oxide, hafnium silicon oxide, lanthanum aluminum oxide, yttrium oxide, lanthanum oxide, silicon nitride, aluminum oxide, silicon oxide, and/or the like. In some embodiments, the second dielectric material 108b may comprise one or more of strontium titanium oxide, tantalum oxide, barium zirconium oxide, zirconium oxide, hafnium oxide, hafnium silicon oxide, lanthanum aluminum oxide, yttrium oxide, lanthanum oxide, silicon nitride, and/or the like. In some embodiments, the third dielectric material 108c may comprise one or more of zirconium oxide, hafnium oxide, hafnium silicon oxide, lanthanum aluminum oxide, yttrium oxide, lanthanum oxide, silicon nitride, aluminum oxide, silicon oxide, and/or the like. In some embodiments, the fourth dielectric material 108d may comprise one or more of aluminum oxide, titanium oxide, tantalum oxide, zirconium oxide, hafnium oxide, magnesium oxide, scandium oxide, silicon oxide, and/or the like.

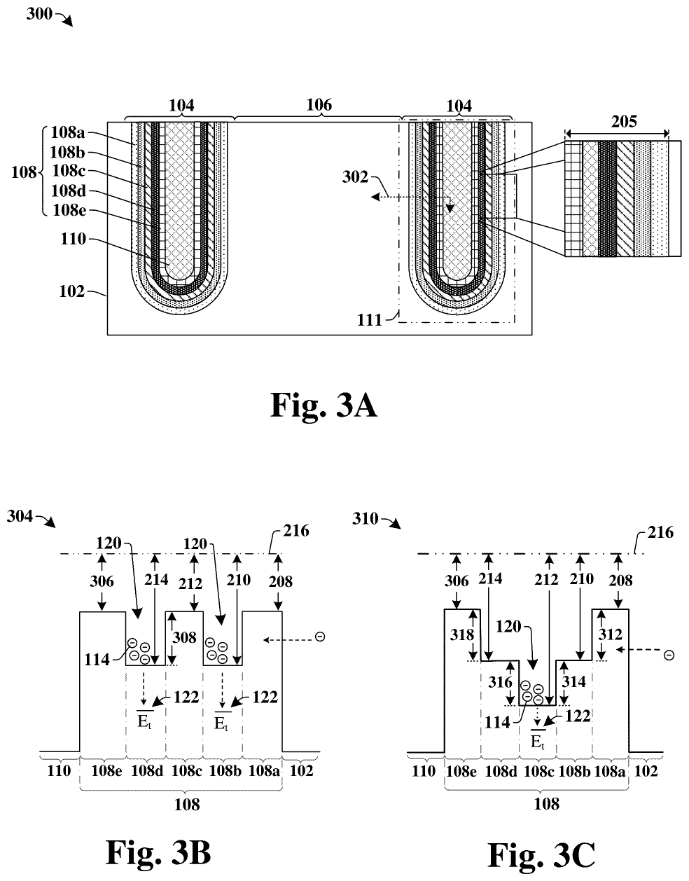

FIG. 3A illustrates some additional embodiments of an integrated chip 300 comprising a trench isolation structure having a multi-layer film stack that forms a potential well configured to trap charge carriers.

The integrated chip 300 comprises a substrate 102 having one or more trenches 104 arranged along opposing sides of a device region 106 comprising a semiconductor device (e.g., a transistor device, an image sensor element, and/or the like). A trench isolation structure 111 is arranged within the one or more trenches 104. The trench isolation structure 111 comprises a multi-layer film stack 108 laterally surrounding a core material 110. In various embodiments, the core material 110 may comprise a conductive material (e.g., aluminum, tungsten, doped polysilicon, and/or the like) or a dielectric material (e.g., aluminum oxide, hafnium oxide, silicon oxide, silicon nitride, and/or the like).

The multi-layer film stack 108 comprises a plurality of dielectric materials 108a-108e stacked onto one another. For example, the multi-layer film stack 108 may comprise a first dielectric material 108a arranged on one or more interior surfaces of the substrate 102 forming the one or more trenches 104, a second dielectric material 108b stacked onto the first dielectric material 108a, a third dielectric material 108c stacked onto the second dielectric material 108b, a fourth dielectric material 108d stacked onto the third dielectric material 108c, and a fifth dielectric material 108e stacked on the fourth dielectric material 108d. In some embodiments, the plurality of dielectric materials 108a-108e may have a total thickness 205 that is in a range of between approximately 50 nanometers nm and approximately 100 nm. In some embodiments, the multi-layer film stack 108 may comprise one or more additional dielectric materials.

In some embodiments, the plurality of dielectric materials 108a-108c may respectively comprise an oxide, a nitride, a dielectric material, a high-k dielectric material, and/or the like. In some embodiments, the first dielectric material 108a may comprise one or more of zirconium oxide, hafnium oxide, hafnium silicon oxide, lanthanum aluminum oxide, yttrium oxide, lanthanum oxide, silicon nitride, aluminum oxide, silicon oxide, and/or the like. In some embodiments, the second dielectric material 108b may comprise one or more of strontium titanium oxide, tantalum oxide, barium zirconium oxide, zirconium oxide, hafnium oxide, hafnium silicon oxide, lanthanum aluminum oxide, yttrium oxide, lanthanum oxide, silicon nitride, and/or the like. In some embodiments, the third dielectric material 108c may comprise one or more of zirconium oxide, hafnium oxide, hafnium silicon oxide, lanthanum aluminum oxide, yttrium oxide, lanthanum oxide, silicon nitride, aluminum oxide, silicon oxide, and/or the like. In some embodiments, the fourth dielectric material 108d may comprise one or more of strontium titanium oxide, tantalum oxide, barium zirconium oxide, zirconium oxide, hafnium oxide, hafnium silicon oxide, lanthanum aluminum oxide, yttrium oxide, lanthanum oxide, silicon nitride, and/or the like. In some embodiments, the fifth dielectric material 108e may comprise one or more of zirconium oxide, hafnium oxide, hafnium silicon oxide, lanthanum aluminum oxide, yttrium oxide, lanthanum oxide, silicon nitride, aluminum oxide, silicon oxide, and/or the like.

The plurality of dielectric materials 108a-108e have different electron affinities (e.g., different energy values between a conductive band energy and a vacuum energy) that form one or more potential wells within the multi-layer film stack 108. FIGS. 3B and 3C show exemplary energy band diagrams associated with the disclosed multi-layer film stack 108. It will be appreciated that the exemplary energy band diagrams shown in FIGS. 3B and 3C are not limiting examples and that the disclosed multi-layer film stack may have energy band diagrams with alternative shapes.

FIG. 3B illustrates an exemplary energy band diagram 304 taken along line 302 of FIG. 3A.

As shown in energy band diagram 304, the first dielectric material 108a has a first electron affinity 208, the second dielectric material 108b has a second electron affinity 210, the third dielectric material 108c has a third electron affinity 212, the fourth dielectric material 108d has a fourth electron affinity 214, and the fifth dielectric material 108e has a fifth electron affinity 306. The first electron affinity 208, the third electron affinity 212, and the fifth electron affinity 306 are less than the second electron affinity 210 and the fourth electron affinity 214, thereby forming a first potential well 120a at a location of the second dielectric material 108b and a second potential well 120b at a location of the fourth dielectric material 108d. In various embodiments, the first electron affinity 208 may be greater than, less than, or substantially equal to the third electron affinity 212 and the fifth electron affinity 306. In various embodiments, the second electron affinity 210 may be greater than, less than, or substantially equal to the fourth electron affinity 214. In some embodiments, the first potential well 120a and the second potential well 120b may respectively have a depth 308 that is greater than approximately 0.001 eV, greater than approximately 0.01 eV, less than approximately 1 eV, greater than approximately 1 eV, or other similar values.

In some embodiments, treatments (e.g., thermal treatments, electrical treatments, etc.) may be applied during fabrication of the multi-layer film stack 108 to cause electrons 114 from within the substrate 102 and/or the core material 110 to tunnel through the potential energy barrier of the first dielectric material 108a and/or the fifth dielectric material 108e and into the first potential well 120a and the second potential well 120b. The electrons 114 become trapped in the first potential well 120a and the second potential well 120b and increase a charge of the multi-layer film stack 108.

FIG. 3C illustrates an exemplary energy band diagram 310 taken along line 302 of FIG. 3A.

As shown in energy band diagram 310, the first electron affinity 208 and the fifth electron affinity 306 are less than the second electron affinity 210 and the fourth electron affinity 214, which are less than the third electron affinity 212, so as to form a potential well 120 having stepped sides within the multi-layer film stack 108. The stepped sides of the potential well 120 may allow for more electrons 114 to tunnel into the potential well 120, thereby increasing a charge within the multi-layer film stack 108 and a passivating effect of the trapped electrons 114 within the potential well 120. This is because the stepped sides of the potential well 120 allow for an energy barrier formed by the first dielectric material 108a and/or the fifth dielectric material 108e to be thinner, thereby increasing a tunneling probability of electrons into the potential well 120. Furthermore, electrons stored in the third dielectric material 108c have a reduced escape probability (e.g., due to external noise) due to the depth of the stepped potential well 120.

In various embodiments, the first electron affinity 208 may be greater than, less than, or substantially equal to the fifth electron affinity 306. In various embodiments, the second electron affinity 210 may be greater than, less than, or substantially equal to the fourth electron affinity 214. In some embodiments, a first difference 312 between the first electron affinity 208 and the second electron affinity 210, a second difference 314 between the second electron affinity 210 and the third electron affinity 212, a third difference 316 between the third electron affinity 212 and the fourth electron affinity 214, and a fourth difference 318 between the fourth electron affinity 214 and the fifth electron affinity 306 may be greater than approximately 0.001 eV, greater than approximately 0.01 eV, less than approximately 1 eV, or other similar values.

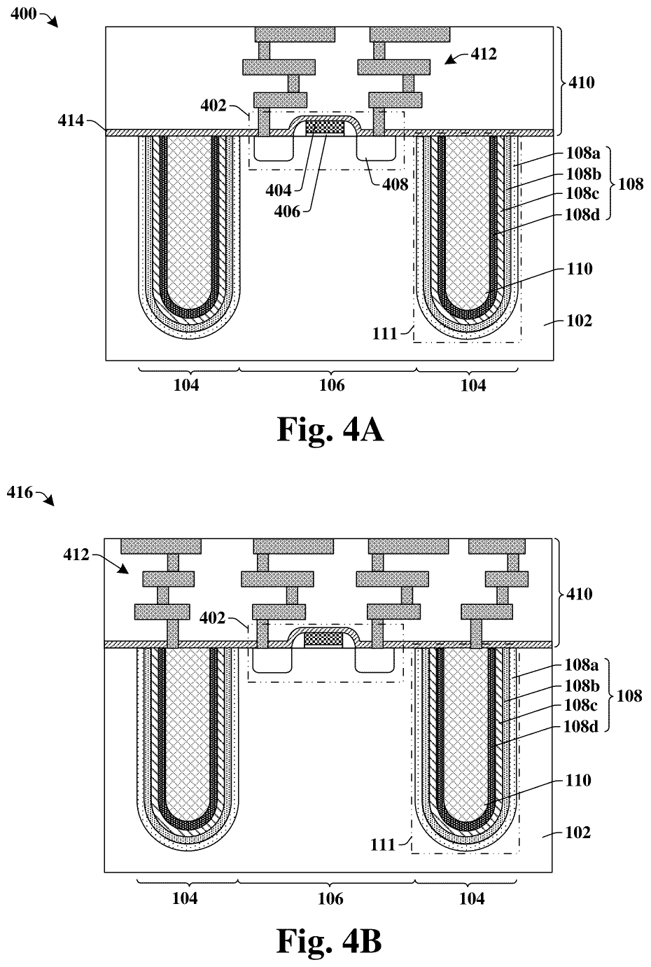

FIG. 4A illustrates a cross-sectional view of some additional embodiments of integrated chip 400 comprising a trench isolation structure having a disclosed multi-layer film stack.

The integrated chip 400 comprises a substrate 102 having one or more trenches 104 arranged along opposing sides of a device region 106. The device region 106 comprises a transistor device 402. The transistor device 402 includes a gate electrode 404 separated from the substrate 102 by a gate dielectric 406. Source/drain regions 408 are arranged along opposing sides of the gate electrode 404. A trench isolation structure 111 is arranged within the one or more trenches 104. The trench isolation structure 111 comprises a multi-layer film stack 108 laterally surrounding a core material 110.

An inter-level dielectric (ILD) structure 410 is arranged on the substrate 102. In some embodiments, the ILD structure 410 comprises one or more inter-level dielectric (ILD) layers stacked onto one another. The ILD structure 410 surrounds one or more interconnects 412. In some embodiments, the one or more interconnects 412 may comprise a conductive contact, a middle-end-of-the-line (MEOL) interconnect, an interconnect wire, and/or an interconnect via. In some embodiments, the ILD structure 410 may comprise a contact etch stop layer (CESL) 414 arranged on the substrate 102. In some embodiments, the ILD structure 410 (e.g., the CESL 414) may contact topmost surfaces of the first dielectric material 108a, the second dielectric material 108b, the third dielectric material 108c, the fourth dielectric material 108d, and the core material 110.

FIG. 4B illustrates a cross-sectional view of some additional embodiments of integrated chip 416 comprising a trench isolation structure having a disclosed multi-layer film stack.

The integrated chip 416 comprises a substrate 102 having one or more trenches 104 arranged along opposing sides of a device region 106 comprising a transistor device 402. A trench isolation structure 111 is arranged within the one or more trenches 104. The trench isolation structure 111 comprises a multi-layer film stack 108 laterally surrounding a core material 110. The core material 110 is conductive.

An ILD structure 410 is arranged on the substrate 102. The ILD structure 410 surrounds one or more interconnects 412. The one or more interconnects 412 are electrically coupled to the core material 110. The one or more interconnects 412 are configured to provide a voltage to the core material 110. The voltage can cause an electric field to form between the core material 110 and the substrate 102. The electric field attracts charge carriers (e.g., electrons) towards the core material 110. In some embodiments, the charge carriers may tunnel into one or more potential wells within the multi-layer film stack 108. In some embodiments, the one or more interconnects 412 may be coupled to one or more additional interconnects disposed along an opposing side of the substrate 102 by way of a through substrate via (TSV).

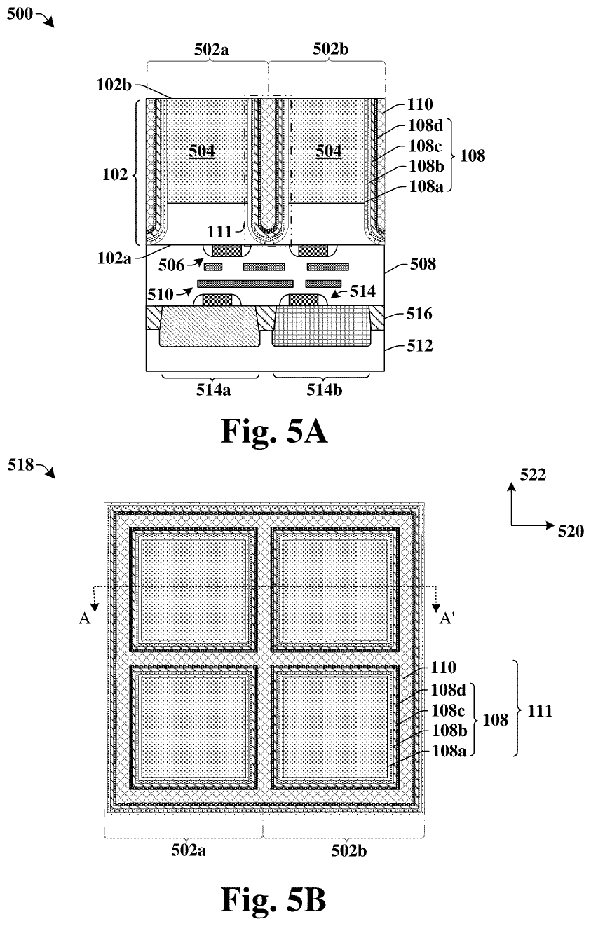

FIGS. 5A-5B illustrate some embodiments of an image sensor integrated chip comprising a trench isolation structure having a disclosed multi-layer film stack.

FIG. 5A illustrates a cross-sectional view 500 of some embodiments of an image sensor integrated chip comprising a trench isolation structure having a disclosed multi-layer film stack.

As shown in cross-sectional view 500, the image sensor integrated chip comprises a substrate 102 having device regions including a plurality of pixel regions 502a-502b. The plurality of pixel regions 502a-502b respectively comprise an image sensing element 504 configured to convert incident radiation (e.g., photons) into an electric signal (i.e., to generate electron-hole pairs from the incident radiation). In some embodiments, the image sensing element 504 may comprise a photodiode.

A plurality of gate structures 506 are arranged along a first side 102a of the substrate 102. A dielectric structure 508 is also arranged along the first side 102a of the substrate 102. The dielectric structure 508 surrounds a plurality of conductive interconnects 510. In some embodiments, the dielectric structure 508 comprises a plurality of stacked ILD layers and the plurality of conductive interconnects 510 comprise alternating layers of conductive vias and conductive wires, which are electrically coupled to the plurality of gate structures 506. In some embodiments, the plurality of gate structures 506 may comprise a plurality of transfer gates.

In some embodiments, a second substrate 512 is coupled to the dielectric structure 508. A plurality of transistor devices 514 are arranged on the second substrate 512. In some embodiments, the plurality of transistor devices 514 may comprise a first type of transistor device 514a (e.g., an NMOS transistor) and a second type of transistor device 514b (e.g., a PMOS transistor). In some embodiments, the plurality of transistor devices 514 may be separated by shallow trench isolation structures 516. In some embodiments, the plurality of transistor devices 514 may comprise support circuitry. For example, the plurality of transistor devices 514 may comprise one or more of a row decoder, pixel support devices, a reset driver, a select driver, column amplifiers and/or capacitors, column decoders (e.g., multiplexors), analog to digital converters, and/or the like.

The plurality of pixel regions 502a-502b are separated by one or more trench isolation structures 111 disposed within one or more trenches extending from the second side 102b of the substrate 102 to within the substrate 102. The one or more trench isolation structures 111 comprises a multi-layer film stack 108 and a core material 110. In some embodiments, the one or more trench isolation structures 111 vertically extend from the second side 102b of the substrate to the first side 102a of the substrate 102. In some additional embodiments (not shown), the one or more trench isolation structures 111 vertically extend from the second side 102b of the substrate to within the dielectric structure 508.

FIG. 5B illustrates some embodiments of a top-view 518 of the disclosed image sensor integrated chip structure of FIG. 5A. In some embodiments, the cross-sectional view of FIG. 5A is taken along line A-A′ of top-view 518.

As shown in top-view 518, the plurality of pixel regions 502a-502b are arranged in the substrate in rows and columns. The rows extend in a first direction 520 and the columns extend in a second direction 522 that is perpendicular to the first direction 520. The one or more trench isolation structures 111 are arranged along opposing sides of the plurality of pixel regions 502a-502b. In some embodiments, the one or more trench isolation structures 111 surround the plurality of pixel regions 502a-502b along the first direction 520 and the second direction 522. In some embodiments, the one or more trench isolation structures 111 continuously wrap around multiple sides of respective ones of the plurality of pixel regions 502a-502b, as viewed in the top-view 518. In some embodiments, the one or more trench isolation structures 111 may wrap around the plurality of pixel regions 502a-502b in a closed and unbroken loop.

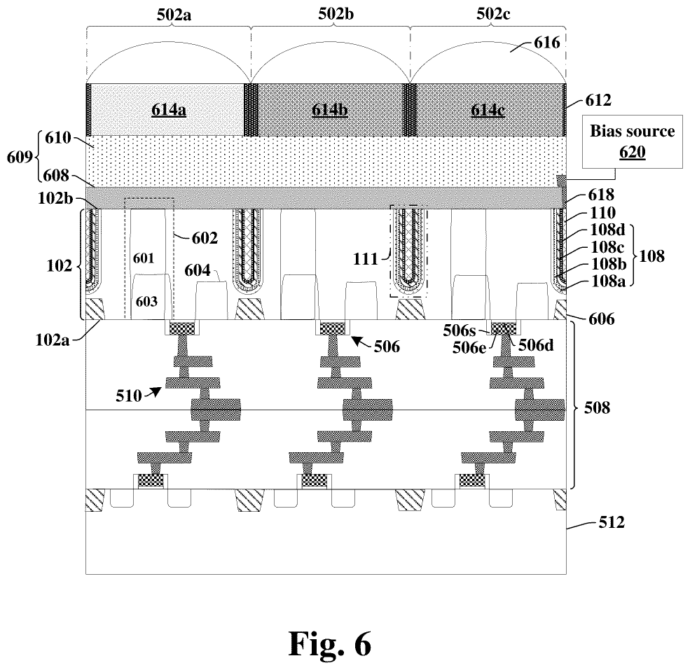

FIG. 6 illustrates a cross-sectional view of some embodiments of an image sensor integrated chip 600 comprising a trench isolation structure having a disclosed multi-layer film stack that forms a potential well configured to trap charge carriers.

The image sensor integrated chip 600 comprises a plurality of gate structures 506 arranged along a first side 102a (e.g., a front-side) of a substrate 102. The plurality of gate structures 506 respectively comprise a gate dielectric layer 506d disposed along the first side 102a of the substrate 102 and a gate electrode 506e arranged on the gate dielectric layer 506d. In some embodiments, sidewall spacers 506s are arranged on opposing sides of the gate electrode 506e. In some embodiments, a gate structure 506 corresponding to a transfer transistor is laterally arranged between a photodiode 602 and a floating diffusion well 604 within the substrate 102. In such embodiments, the photodiode 602 may comprise a first region 601 having a first doping type (e.g., n-type doping) and an adjoining second region 603 having a second doping type (e.g., p-type doping) that is different than the first doping type. The gate structure 506 is configured to control a transfer of charge from the photodiode 602 to the floating diffusion well 604. If a charge level is sufficiently high within the floating diffusion well 604, a source-follower transistor (not shown) is activated and charges are selectively output according to operation of a row select transistor (not shown) used for addressing. A reset transistor (not shown) is configured to reset the photodiode 602 between exposure periods.

A dielectric structure 508 is also arranged along the first side 102a (e.g., front-side) of the substrate 102. The dielectric structure 508 may comprise a plurality of stacked ILD layers. In various embodiments, the plurality of stacked ILD layers may comprise one or more of an oxide (e.g., SiO₂, SiCO, etc.), a fluorosilicate glass, a phosphate glass (e.g., borophosphate silicate glass), etc. The dielectric structure 508 surrounds a plurality of conductive interconnects 510 electrically coupled to the gate structures 506. In some embodiments, the plurality of conductive interconnects 510 may comprise one or more of copper, aluminum, tungsten, and carbon nanotubes, and/or the like. In some embodiments, the dielectric structure 508 is coupled to a second substrate 512 (e.g., a carrier substrate). In some embodiments, the second substrate 512 may comprise silicon.

In some embodiments, a plurality of shallow trench isolation (STI) structures 606 are also arranged within the first side 102a of the substrate 102. The plurality of STI structures 606 comprise one or more dielectric materials (e.g., SiO₂) arranged within trenches in the first side 102a of the substrate 102. A plurality of trench isolation structures 111 are arranged within one or more trenches within a second side 102b (e.g., a back-side) of the substrate 102 over the plurality of STI structures 606. The plurality of trench isolation structures 111 comprise a multi-layer film stack 108 surrounding a core material 110. In some embodiments, the plurality of trench isolation structures 111 may respectively have a width that is smaller than a width of one of the plurality of STI structures 606. In some embodiments, one or more isolation well regions (not shown) may be arranged between the plurality of STI structures 606 and the plurality of trench isolation structures 111. The one or more isolation well regions may comprise doped regions that provide further isolation between adjacent ones of the plurality of pixel regions 502a-502b by way of junction isolation.

In some embodiments, a dielectric structure 609 is arranged along the second side 102b of the substrate 102. The dielectric structure 609 may comprise an anti-reflection structure 608 and a dielectric planarization structure 610 having a substantially planar surface facing away from the substrate 102. In some embodiments, the anti-reflection structure 608 may comprise a high-k dielectric layer including hafnium oxide (HfO₂), titanium oxide (TiO₂), hafnium zirconium oxide (HfZrO), tantalum oxide (Ta₂O₃), hafnium silicon oxide (HfSiO₄), zirconium oxide (ZrO₂), zirconium silicon oxide (ZrSiO₂), an oxide (e.g., silicon oxide), TEOS, etc. In various embodiments, the dielectric planarization structure 610 may comprise an oxide (e.g., SiO₂) and/or a nitride.

A grid structure 612 is disposed on the dielectric structure 609. The grid structure 612 comprises sidewalls that form openings overlying the plurality of pixel regions 502a-502c. In various embodiments, the grid structure 612 may comprise a metal (e.g., aluminum, cobalt, copper, silver, gold, tungsten, etc.) and/or a dielectric material (e.g., SiO₂, SiN, etc.). A plurality of color filters, 614a-614c, are arranged within the openings in the grid structure 612. The plurality of color filters, 614a-614c, are respectively configured to transmit specific wavelengths of incident radiation. For example, a first color filter 614a may transmit radiation having wavelengths within a first range (e.g., corresponding to green light), while a second color filter 614b may transmit radiation having wavelengths within a second range (e.g., corresponding to red light) different than the first range, etc. A plurality of micro-lenses 616 are arranged over the plurality of color filters 614a-614c. Respective ones of the plurality of micro-lenses 616 are laterally aligned with the plurality of color filters, 614a-614c, and overlie the plurality of pixel regions 502a-502c. The plurality of micro-lenses 616 are configured to focus the incident radiation (e.g., light) towards the plurality of pixel regions 502a-502c.

In some embodiments, one or more conductive routing layers 618 may be arranged on or within the dielectric structure 609. The one or more conductive routing layers 618 electrically couple the core material 110 to a bias source 620 (e.g., via a port located outside of the pixel regions 502a-502c). In some embodiments, the one or more conductive routing layers 618 may be arranged below the grid structure 612 so as to not block incident radiation from reaching the plurality of pixel regions 502a-502c.

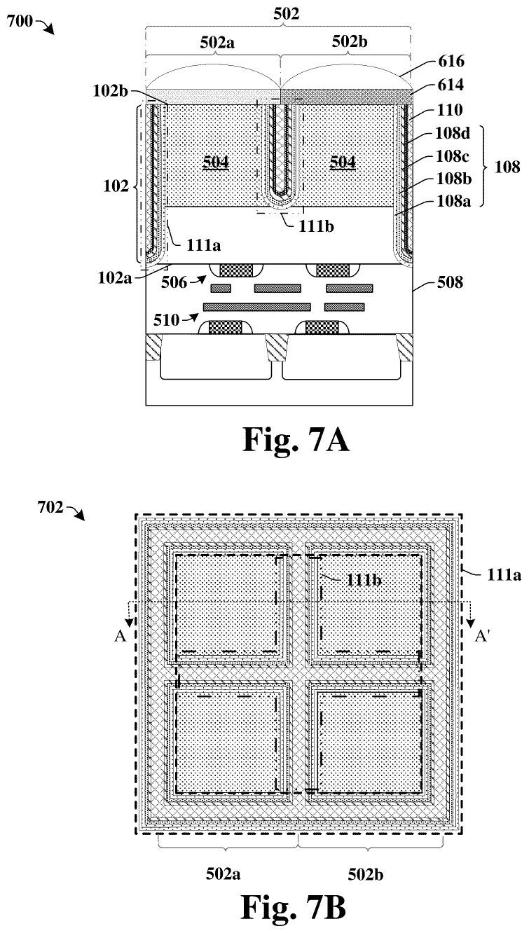

FIGS. 7A-7B illustrate some embodiments of an image sensor integrated chip comprising a trench isolation structure having a disclosed multi-layer film stack that forms a potential well configured to trap charge carriers.

As shown in cross-sectional view 700 of FIG. 7A, the image sensor integrated chip comprises a substrate 102 having device regions including a plurality of pixel regions 502a-502b. The plurality of pixel regions 502a-502b respectively comprise an image sensing element 504 (e.g., a photodiode). In some embodiments, the plurality of pixel regions 502a-502b may be parts of a dual-photodiode pixel region 502 that is configured to include a pair of photodiodes. A plurality of gate structures 506 are arranged along a first side 102a of the substrate 102. A dielectric structure 508 is also arranged along the first side 102a of the substrate 102. The dielectric structure 508 surrounds a plurality of conductive interconnects 510.

The plurality of pixel regions 502a-502b are separated by trench isolation structures 111a-111b disposed within one or more trenches extending from a second side 102b of the substrate 102 to within the substrate 102. The trench isolation structures 111a-111b comprise a multi-layer film stack 108 and a core material 110. The trench isolation structures 111a-111b may include one or more first trench isolation structures 111a and one or more second trench isolation structures 111b. The one or more first trench isolation structures 111a vertically extend from the second side 102b of the substrate to the first side 102a of the substrate 102. In some embodiments, the one or more first trench isolation structures 111a vertically extend from the second side 102b of the substrate 102 to within the dielectric structure 508. The one or more second trench isolation structures 111b vertically extend from the second side 102b of the substrate to a non-zero distance from the first side 102a of the substrate 102.

FIG. 7B illustrates some embodiments of a top-view 702 of the disclosed image sensor integrated chip structure of FIG. 7A. In some embodiments, the cross-sectional view of FIG. 7A is taken along line A-A′ of top-view 702.

The top-view 702 shows that the one or more first trench isolation structures 111a are arranged around a perimeter of the plurality of pixel regions 502a-502b, while the one or more second trench isolation structures 111b separate adjacent ones of the plurality of pixel regions 502a-502b.

In various embodiments, the disclosed trench isolation structure can be disposed within one or more trenches arranged along different sides of the substrate and/or extending to different depths within a substrate. FIGS. 8-11 illustrate some additional embodiments of image sensor integrated chips having different configurations of trench isolation structures.

FIG. 8 illustrates a cross-sectional view of some embodiments of an image sensor integrated chip 800 comprising a plurality trench isolation structures having a disclosed multi-layer film stack.

The image sensor integrated chip 800 comprises a substrate 102 having a plurality of pixel regions 502a-502b respectively comprising an image sensing element 504. A plurality of gate structures 506 are disposed along a first side 102a (e.g., a front-side) of the substrate 102. A dielectric structure 508 is disposed on the first side 102a of the substrate 102 and around the plurality of gate structures 506. A plurality of color filters 614 are disposed on a second side 102b (e.g., a back-side) of the substrate 102 opposing the first side 102a. A plurality of micro-lenses 616 are arranged on the plurality of color filters 614.

A plurality of trench isolation structures 111 are disposed along opposing sides of the plurality of pixel regions 502a-502b. The plurality of trench isolation structures 111 respectively extend through a part, but not all, of the substrate 102 (e.g., from the second side 102b of the substrate 102 to a non-zero distance from the first side 102a of the substrate 102). In some embodiments, the plurality of trench isolation structures 111 have a width that decreases towards the first side 102a of the substrate 102. The plurality of trench isolation structures 111 respectively comprise a multi-layer film stack 108 surrounding a core material 110. In some embodiments, the multi-layer film stack 108 extends around the core material 110 and has an open end along the second side 102b of the substrate 102.

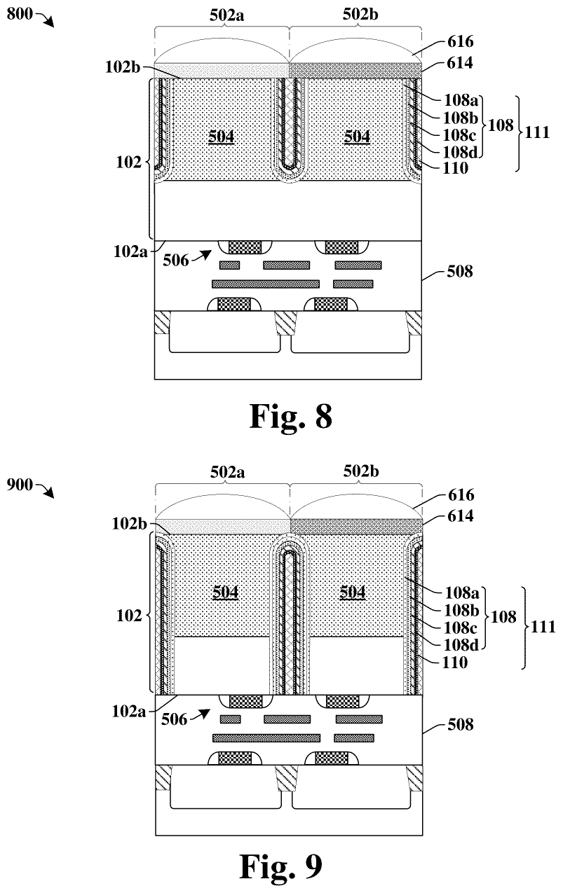

FIG. 9 illustrates a cross-sectional view of some embodiments of an image sensor integrated chip 900 comprising a plurality trench isolation structures having a disclosed multi-layer film stack.

The image sensor integrated chip 900 comprises a substrate 102 having a plurality of pixel regions 502a-502b respectively comprising an image sensing element 504. A plurality of gate structures 506 are disposed along a first side 102a (e.g., a front-side) of the substrate 102. A dielectric structure 508 is disposed on the first side 102a of the substrate 102 and around the plurality of gate structures 506. A plurality of color filters 614 are disposed on a second side 102b (e.g., a back-side) of the substrate 102 opposing the first side 102a. A plurality of micro-lenses 616 are arranged on the plurality of color filters 614.

A plurality of trench isolation structures 111 are disposed along opposing sides of the plurality of pixel regions 502a-502b. The plurality of trench isolation structures 111 respectively extend completely through the substrate 102 (e.g., from the first side 102a of the substrate 102 to the second side 102b of the substrate 102). In some embodiments, the plurality of trench isolation structures 111 have a width that decreases towards the second side 102b of the substrate 102. The plurality of trench isolation structures 111 respectively comprise a multi-layer film stack 108 surrounding a core material 110. In some embodiments, the multi-layer film stack 108 extends around the core material 110 and has an open end along the first side 102a of the substrate 102.

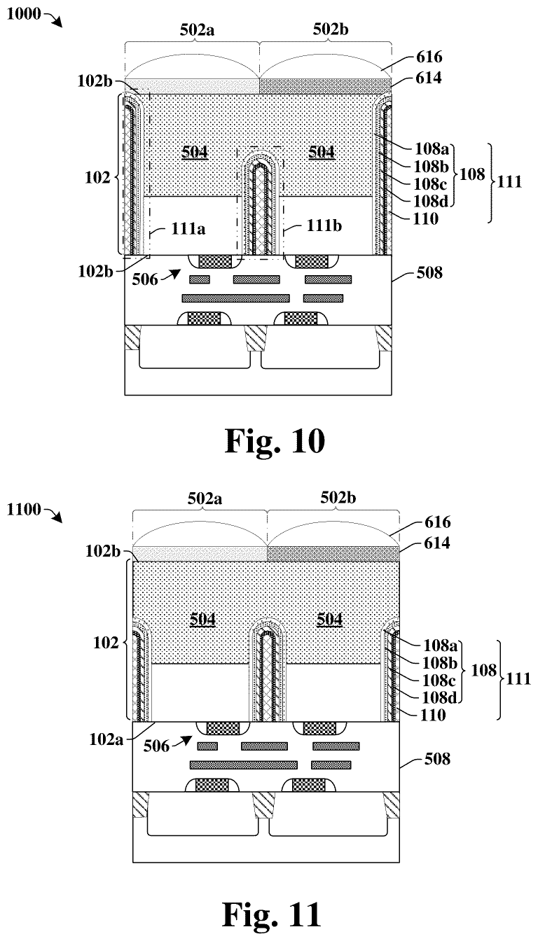

FIG. 10 illustrates a cross-sectional view of some embodiments of an image sensor integrated chip 1000 comprising a plurality trench isolation structures having a disclosed multi-layer film stack.

The image sensor integrated chip 1000 comprises a substrate 102 having a plurality of pixel regions 502a-502b respectively comprising an image sensing element 504. A plurality of gate structures 506 are disposed along a first side 102a (e.g., a front-side) of the substrate 102. A dielectric structure 508 is disposed on the first side 102a of the substrate 102 and around the plurality of gate structures 506. A plurality of color filters 614 are disposed on a second side 102b (e.g., a back-side) of the substrate 102 opposing the first side 102a. A plurality of micro-lenses 616 are arranged on the plurality of color filters 614.

A plurality of trench isolation structures 111 are disposed along opposing sides of the plurality of pixel regions 502a-502b. The plurality of trench isolation structures 111 comprise one or more first trench isolation structures 111a that respectively extend completely through the substrate 102 (e.g., from the first side 102a of the substrate 102 to the second side 102b of the substrate 102) and one or more second trench isolation structures 111b that respectively extend through a part, but not all, of the substrate 102 (e.g., from the first side 102a of the substrate 102 to a non-zero distance from the second side 102b of the substrate 102). In some embodiments, the plurality of trench isolation structures 111 have a width that decreases towards the second side 102b of the substrate 102. The plurality of trench isolation structures 111 respectively comprise a multi-layer film stack 108 surrounding a core material 110. In some embodiments, the multi-layer film stack 108 extends around the core material 110 and has an open end along the first side 102a of the substrate 102.

FIG. 11 illustrates a cross-sectional view of some embodiments of an image sensor integrated chip 1100 comprising a plurality trench isolation structures having a disclosed multi-layer film stack.

The image sensor integrated chip 1100 comprises a substrate 102 having a plurality of pixel regions 502a-502b respectively comprising an image sensing element 504. A plurality of gate structures 506 are disposed along a first side 102a (e.g., a front-side) of the substrate 102. A dielectric structure 508 is disposed on the first side 102a of the substrate 102 and around the plurality of gate structures 506. A plurality of color filters 614 are disposed on a second side 102b (e.g., a back-side) of the substrate 102 opposing the first side 102a. A plurality of micro-lenses 616 are arranged on the plurality of color filters 614.

A plurality of trench isolation structures 111 are disposed along opposing sides of the plurality of pixel regions 502a-502b. The plurality of trench isolation structures 111 respectively extend through a part, but not all, of the substrate 102 (e.g., from the first side 102a of the substrate 102 to a non-zero distance from the second side 102b of the substrate 102). In some embodiments, the plurality of trench isolation structures 111 have a width that decreases towards the second side 102b of the substrate 102. The plurality of trench isolation structures 111 respectively comprise a multi-layer film stack 108 surrounding a core material 110. In some embodiments, the multi-layer film stack 108 extends around the core material 110 and has an open end along the first side 102a of the substrate 102

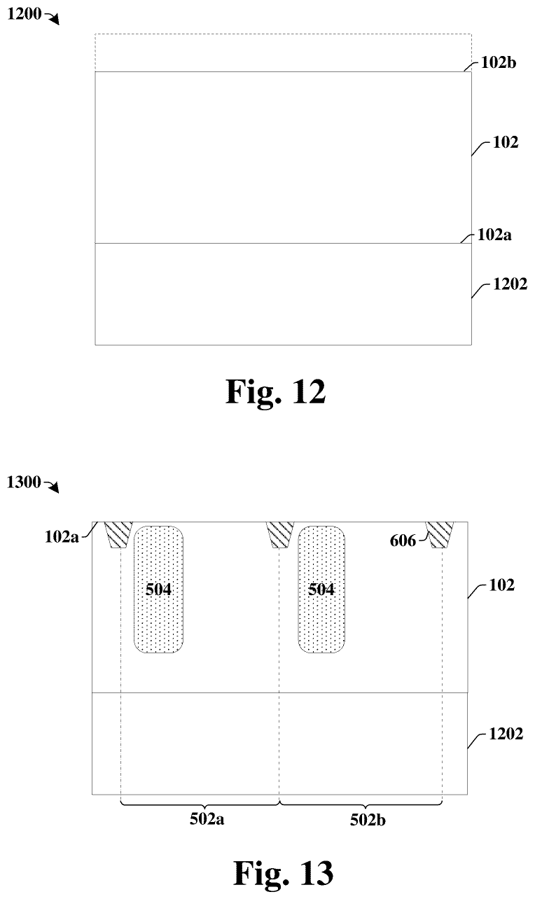

FIGS. 12-26 illustrate cross-sectional views 1200-2600 of some embodiments of a method of forming an integrated chip comprising a trench isolation structure having a multi-layer film stack that forms one or more potential wells configured to trap charge carriers. Although the cross-sectional views 120-2600 shown in FIGS. 12-26 are described with reference to a method, it will be appreciated that the structures shown in FIGS. 12-26 are not limited to the method of formation but rather may stand alone separate of the method.

As shown in cross-sectional view 1200 of FIG. 12, a substrate 102 is provided. In various embodiments, the substrate 102 may be any type of substrate (e.g., silicon, SiGe, SOI, etc.), such as a semiconductor wafer, as well as any other type of semiconductor and/or epitaxial layers, associated therewith. The substrate 102 has a first side 102a and a second side 102b, which opposes the first side 102a. In some embodiments, the substrate 102 may be coupled to a carrier substrate 1202 and then thinned to reduce a thickness of the substrate 102. In some embodiments, an etching process or a mechanical grinding process may be used to thin the substrate 102.

As shown in cross-sectional view 1300 of FIG. 13, an image sensing element 504 is formed within a plurality of pixel regions 502a-502b within the substrate 102. In some embodiments, the image sensing element 504 may comprise a photodiode formed by implanting one or more dopant species into the first side 102a of the substrate 102. For example, the image sensing element 504 may be formed by selectively performing a first implantation process (e.g., according to a masking layer) to form a first region having a first doping type (e.g., n-type) and subsequently performing a second implantation process to form a second region abutting the first region and having a second doping type (e.g., p-type) different than the first doping type. In some embodiments, a floating diffusion well (not shown) may also be formed using one of the first or second implantation processes. In some embodiments, one or more shallow trench isolation (STI) structures 606 may be formed within the first side 102a of the substrate along opposing sides of the plurality of pixel regions 502a-502b.

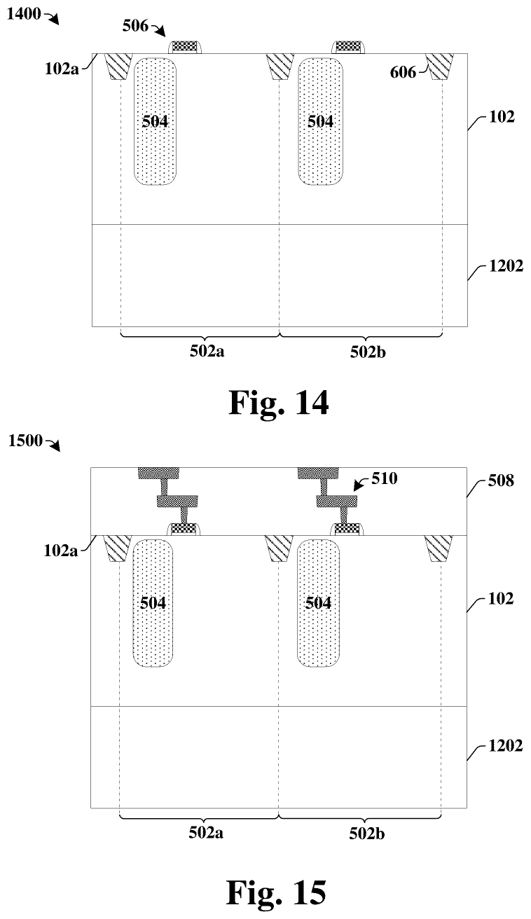

As shown in cross-sectional view 1400 of FIG. 14, a plurality of gate structures 506 are formed along the first side 102a of the substrate 102. In some embodiments, the plurality of gate structures 506 may be formed by forming a gate dielectric layer on the first side 102a of the substrate 102. In some embodiments, the gate dielectric layer may be deposited by a deposition process (e.g., a physical vapor deposition (PVD) process, a chemical vapor deposition (CVD) process, a plasma enhanced CVD (PE-CVD) process, an atomic layer deposition (ALD) process, a sputter deposition process, or the like). One or more gate electrodes are formed over the gate dielectric layer. In some embodiments, the one or more gate electrodes are formed by depositing a gate electrode layer onto the gate dielectric layer followed by a patterning process that selectively etches the gate electrode layer and the gate dielectric layer.

As shown in cross-sectional 1500 of FIG. 15, one or more conductive interconnects 510 are formed within a dielectric structure 508 formed along the first side 102a of the substrate 102. The dielectric structure 508 comprises a plurality of stacked ILD layers, while the one or more conductive interconnects 510 comprise alternating layers of conductive wires and vias. In some embodiments, one or more of the one or more conductive interconnects 510 may be formed using a damascene process (e.g., a single damascene process or a dual damascene process). The damascene process is performed by forming an ILD layer over the first side 102a of the substrate 102, etching the ILD layer to form a via hole and/or a trench, and filling the via hole and/or trench with a conductive material. In some embodiments, the ILD layer may be deposited by a physical vapor deposition technique (e.g., PVD, CVD, PE-CVD, ALD, etc.) and the conductive material may be formed using a deposition process and/or a plating process (e.g., electroplating, electro-less plating, etc.). In various embodiments, the conductive material may comprise tungsten, copper, aluminum, copper, or the like.

In some embodiments (not shown), after forming the dielectric structure 508 the carrier substrate 1202 may be removed. In some embodiments, after removing the carrier substrate 1202, the substrate 102 may be thinned to reduce a thickness of the substrate 102. In some embodiments, the dielectric structure 508 may be bonded to an additional support substrate prior to thinning the substrate 102.

As shown in cross-sectional view 1600 of FIG. 16, a mask 1602 is formed along the second side 102b (e.g., the back-side) of the substrate 102. The mask 1602 comprises sidewalls forming openings along the second side 102b of the substrate 102. In some embodiments, the mask 1602 may be formed by depositing a layer of photosensitive material (e.g., a positive or negative photoresist) along the second side 102b of the substrate 102. The layer of photosensitive material is selectively exposed to electromagnetic radiation according to a photomask. The electromagnetic radiation modifies a solubility of exposed regions within the photosensitive material to form soluble regions. The photosensitive material is subsequently developed to form the openings within the photosensitive material by removing the soluble regions.

A patterning process is performed on the second side 102b of the substrate 102 according to the mask 1602. The patterning process forms one or more trenches 104 within the second side 102b of the substrate 102. The one or more trenches 104 vertically extend from the second side 102b of the substrate 102 to within the substrate 102 along opposing sides of the plurality of pixel regions 502a-502b. In some embodiments, the patterning process may selectively expose the substrate 102 to one or more etchants 1604 (e.g., one or more dry etchants) according to the mask 1602. In some embodiments, the one or more etchants 1604 may have an etching chemistry comprising one or more of oxygen (O₂), nitrogen (N₂), hydrogen (H₂), argon (Ar), and/or a fluorine species (e.g., CF₄, CHF₃, C₄F₈, etc.).

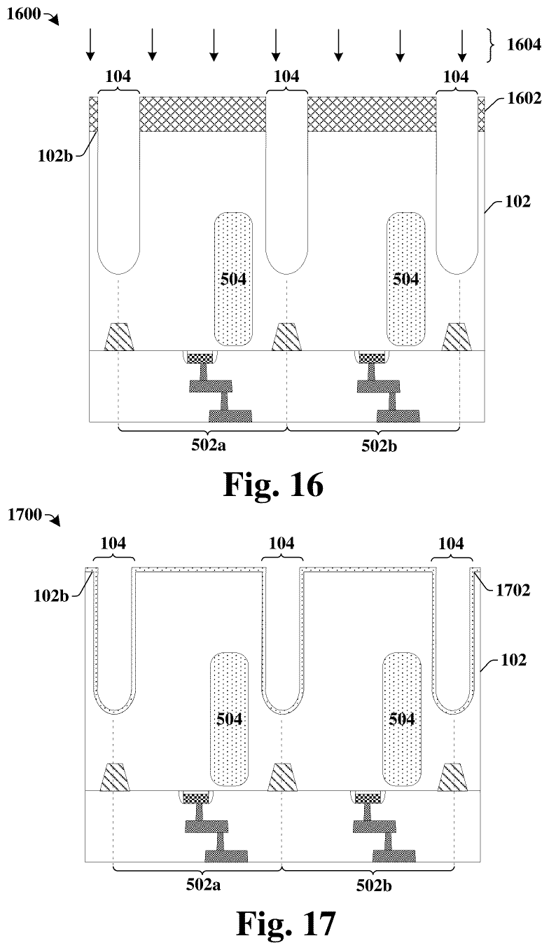

As shown in cross-sectional view 1700 of FIG. 17, a first dielectric layer 1702 is formed on the second side 102b of the substrate 102 and within the one or more trenches 104. The first dielectric layer 1702 may be formed to conformally line sidewalls of the substrate 102. The first dielectric layer 1702 has a first electron affinity. In some embodiments, the first dielectric layer 1702 may comprise one or more of zirconium oxide, hafnium oxide, hafnium silicon oxide, lanthanum aluminum oxide, yttrium oxide, lanthanum oxide, silicon nitride, aluminum oxide, silicon oxide, or the like. In various embodiments, the first dielectric layer 1702 may be deposited by a deposition process (e.g., a PVD process, a CVD process, a PE-CVD process, an ALD process, a sputter deposition process, or the like).

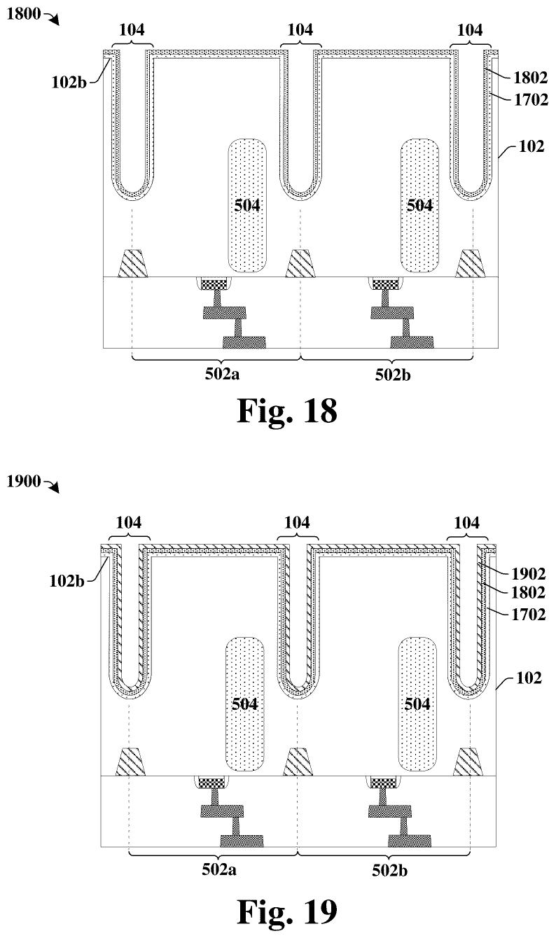

As shown in cross-sectional view 1800 of FIG. 18, a second dielectric layer 1802 is formed on the first dielectric layer 1702 and within the one or more trenches 104. The second dielectric layer 1802 may be formed to conformally line sidewalls of the first dielectric layer 1702. The second dielectric layer 1802 has a second electron affinity. In some embodiments, the second dielectric layer 1802 may comprise one or more of strontium titanium oxide, tantalum oxide, barium zirconium oxide, zirconium oxide, hafnium oxide, hafnium silicon oxide lanthanum aluminum oxide, yttrium oxide, lanthanum oxide, silicon nitride or the like. In various embodiments, the second dielectric layer 1802 may be deposited by a deposition process (e.g., a PVD process, a CVD process, a PE-CVD process, an ALD process, a sputter deposition process, or the like).

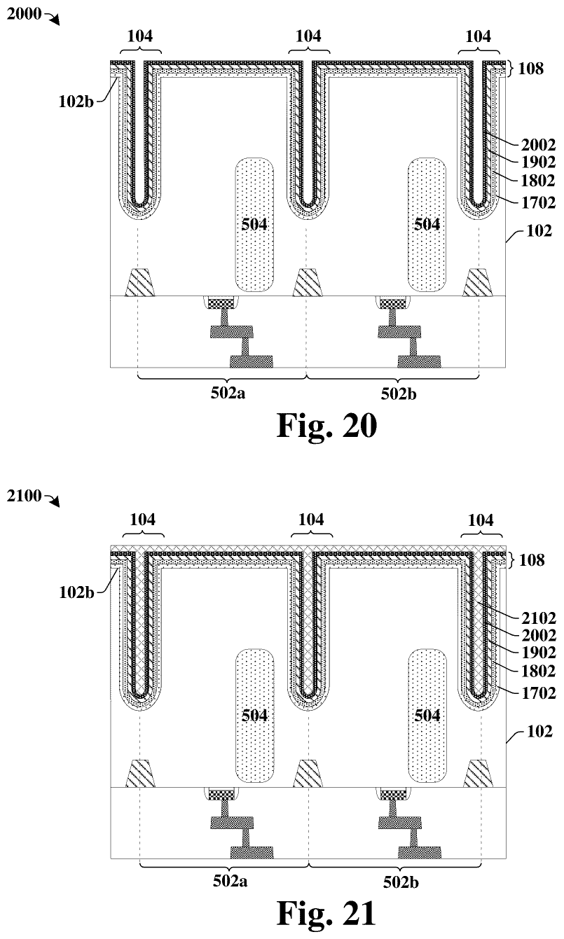

As shown in cross-sectional view 1900 of FIG. 19, a third dielectric layer 1902 is formed on the second dielectric layer 1802 and within the one or more trenches 104. The third dielectric layer 1902 may be formed to conformally line sidewalls of the second dielectric layer 1802. The third dielectric layer 1902 has a third electron affinity. In some embodiments, the third dielectric layer 1902 may comprise one or more of zirconium oxide, hafnium oxide, hafnium silicon oxide, lanthanum aluminum oxide, yttrium oxide, lanthanum oxide, silicon nitride, aluminum oxide, silicon oxide, or the like. In various embodiments, the third dielectric layer 1902 may be deposited by a deposition process (e.g., a PVD process, a CVD process, a PE-CVD process, an ALD process, a sputter deposition process, or the like).

As shown in cross-sectional view 2000 of FIG. 20, a fourth dielectric layer 2002 is formed on the third dielectric layer 1902 and within the one or more trenches 104 to form a multi-layer film stack 108 within the one or more trenches 104. The fourth dielectric layer 2002 may be formed to conformally line sidewalls of the third dielectric layer 1902. The fourth dielectric layer 1802 has a fourth electron affinity. In some embodiments, the fourth dielectric layer 2002 may have a higher oxygen density than the third dielectric layer 1902. In some embodiments, the fourth dielectric layer 2002 may comprise one or more of aluminum oxide, titanium oxide, tantalum oxide, zirconium oxide, hafnium oxide, magnesium oxide, scandium oxide, silicon oxide, and/or the like. In various embodiments, the fourth dielectric layer 2002 may be deposited by a deposition process (e.g., a PVD process, a CVD process, a PE-CVD process, an ALD process, a sputter deposition process, or the like).

In some embodiments (not shown), one or more additional dielectric layers may be formed within the one or more trenches to form the multi-layer film stack 108. For example, in some embodiments a fifth dielectric layer may be formed onto the fourth dielectric layer and within the one or more trenches 104 to form the multi-layer film stack 108. The fifth dielectric layer may be formed to conformally line sidewalls of the fourth dielectric layer 2002. The fifth dielectric layer has a fifth electron affinity. In some embodiments, the fifth dielectric layer may have a higher oxygen density than the fourth dielectric layer 2002. In some embodiments, the fifth dielectric layer may comprise one or more of zirconium oxide, hafnium oxide, hafnium silicon oxide, lanthanum aluminum oxide, yttrium oxide, lanthanum oxide, silicon nitride, aluminum oxide, silicon oxide, or the like. In various embodiments, the fifth dielectric layer may be deposited by a deposition process (e.g., a PVD process, a CVD process, a PE-CVD process, an ALD process, a sputter deposition process, or the like).

As shown in cross-sectional view 2100 of FIG. 21, a core layer 2102 is formed within the one or more trenches 104 and between sidewalls of the fourth dielectric layer 2002. In some embodiments, the core layer 2102 may comprise a conductive material, while in other embodiments the core layer 2102 may comprise a dielectric material. In some embodiments, the core layer 2102 may be formed by way of a deposition process (e.g., a PVD process, a CVD process, a PE-CVD process, an ALD process, a sputter deposition process, or the like) and/or a plating process (e.g., electroplating, electro-less plating, etc.).

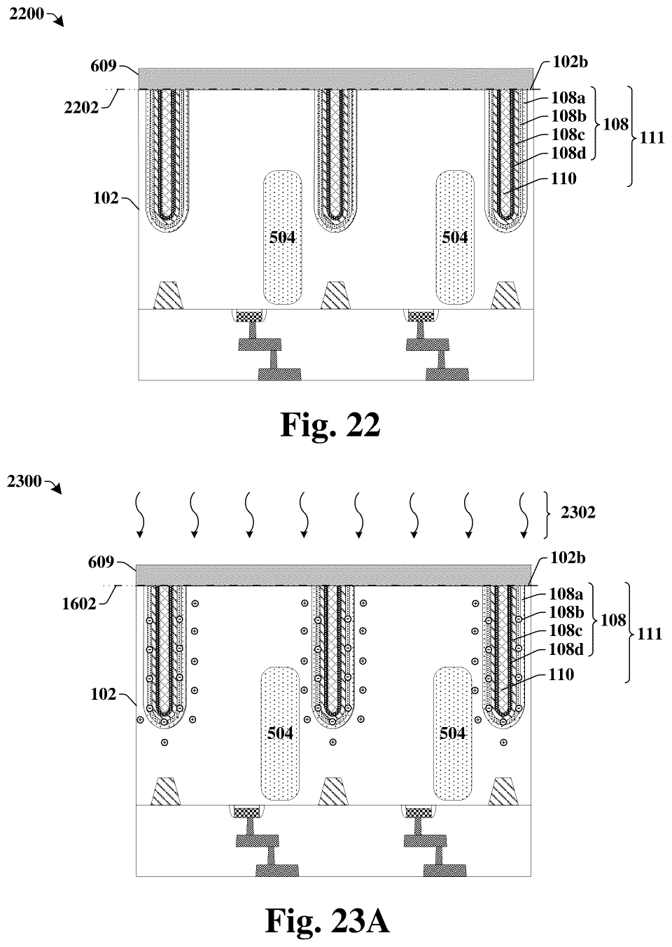

As shown in cross-sectional view 2200 of FIG. 22, a planarization process is performed (along line 2202) to remove parts of the multi-layer film stack 108. The planarization process may remove parts of the first dielectric layer (e.g., 1702 of FIG. 21), the second dielectric layer (e.g., 1802 of FIG. 21), the third dielectric layer (e.g., 1902 of FIG. 21), the fourth dielectric layer (e.g., 2002 of FIG. 21), and the core layer (e.g., 2102 of FIG. 21) that are outside of the one or more trenches 104. In some embodiments, the planarization process may comprise a chemical mechanical polishing (CMP) process. In other embodiments, the planarization process may comprise an etching process, a grinding process, and/or the like.

The planarization process forms one or more trench isolation structures 111 within the one or more trenches 104 in the substrate 102. The one or more trench isolation structures 111 comprise the multi-layer film stack 108 and a core material 110. The multi-layer film stack 108 comprises a plurality of dielectric materials 108a-108d stacked onto one another. For example, the multi-layer film stack 108 may comprise a first dielectric material 108a, a second dielectric material 108b stacked onto the first dielectric material 108a, a third dielectric material 108c stacked onto the second dielectric material 108b, and a fourth dielectric material 108d stacked onto the third dielectric material 108c.

Two or more of the plurality of dielectric materials 108a-108d have different electron affinities. The plurality of dielectric materials 108a-108d are arranged to give the multi-layer film stack 108 a conduction energy band having one or more potential wells. For example, in some embodiments the second electron affinity is larger than the first electron affinity and the third electron affinity, so as to form a potential well at a location corresponding to the second dielectric material 108b. In some embodiments, the second electron affinity and the fourth electron affinity are larger than the first electron affinity, the third electron affinity, and the fifth electron affinity, so as to form potential wells at locations corresponding to the second dielectric material 108b and the fourth dielectric material 108d. In other embodiments, the second electron affinity and the fourth electron affinity are larger than the first electron affinity and the fifth electron affinity and are smaller than the third electron affinity, so as to form a stepped potential well.

A dielectric structure 609 is formed along the second side 102b of the substrate 102. In some embodiments, the dielectric structure 609 may physically contact surfaces of the first dielectric material 108a, the second dielectric material 108b, the third dielectric material 108c, the fourth dielectric material 108d, and the core material 110.

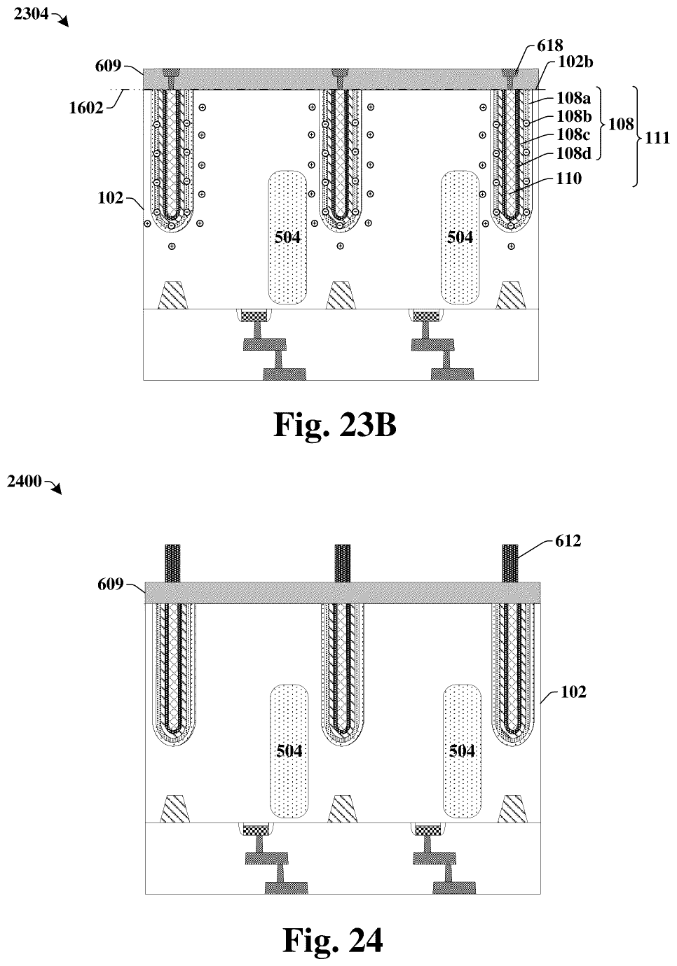

As shown in cross-sectional view 2300 of FIG. 23A, a thermal process 2302 is performed on the substrate 102. In some embodiments, the thermal process 2302 may comprise a furnace process, a rapid thermal anneal, and/or the like. The thermal process 2302 causes charge carriers (e.g., electrons) from within the substrate 102 and/or the core material 110 to tunnel into a potential well within the multi-layer film stack 108. In some embodiments, the thermal process 2302 may be performed by exposing the substrate 102 to an elevated temperature of greater than approximately 100° C., greater than approximately 500° C., in a range of between approximately 100° C. and approximately 1000° C., or other similar values. In some embodiments, the thermal process 2302 may expose the substrate 203 to the elevated temperature for a time of greater than approximately 1 minute, between approximately 1 minute and approximately 2 minutes, between approximately 1 minute and approximately 5 minutes, or other similar values.

In some alternative embodiments, shown in cross-sectional view 2304 of FIG. 23B, one or more conductive routing layers 618 may be formed on or within the dielectric structure 609. The one or more conductive routing layers 618 are electrically coupled to the core material 110. The one or more conductive routing layers 618 may be used to apply a bias voltage to the core material 110. The voltage bias causes charge carriers (e.g., electrons or holes) from within the substrate 102 and/or the core material 110 to tunnel into a potential well within the multi-layer film stack 108. In some embodiments, the bias voltage may have a range of between approximately −5 volt and approximately 5 volts.

As shown in cross-sectional view 2400 of FIG. 24, a grid structure 612 is formed on the dielectric structure 609. The grid structure 612 may comprise a metal that is formed directly over the one or more trench isolation structures 111. In some embodiments, the grid structure 612 may be formed by a deposition process and/or a plating process followed by an etching process.

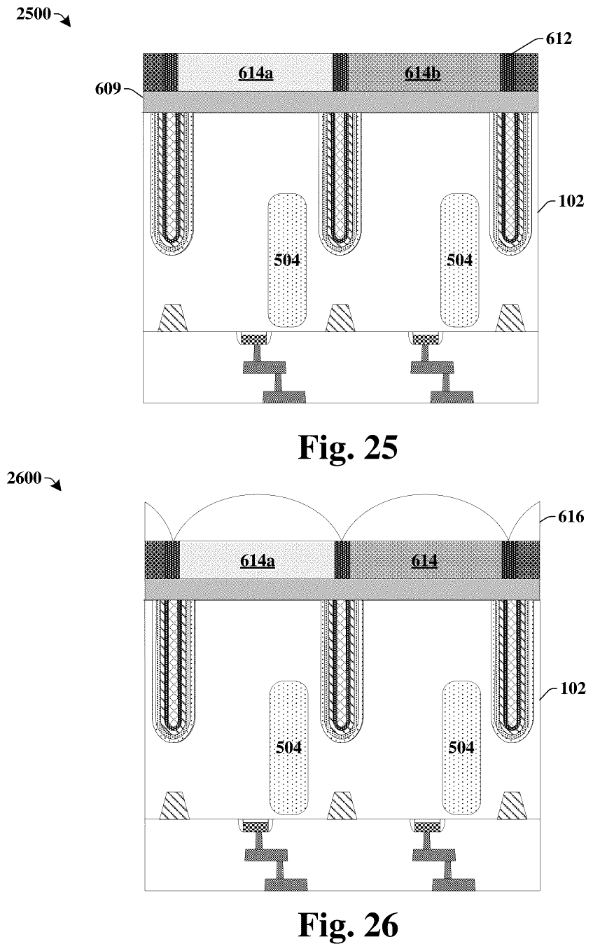

As shown in cross-sectional view 2500 of FIG. 25, a plurality of color filters 614a-614b are formed over the dielectric structure 609 and between sidewalls of the grid structure 612. In some embodiments, the plurality of color filters 614a-614b are formed by depositing (e.g., via CVD, PVD, ALD, sputtering, a spin-on process, etc.) a light filtering material(s) onto the substrate 102. The light filtering material(s) is a material that allows for the transmission of radiation (e.g., light) having a specific wavelength range, while blocking light of wavelengths outside of the specified range. In some embodiments, a planarization process (e.g., CMP) may be subsequently performed on the plurality of color filters 614a-614b to planarize the upper surfaces of the plurality of color filters 614a-614b.

As shown in cross-sectional view 2600 of FIG. 26, a plurality of micro-lenses 616 are formed over the plurality of color filters 614a-614b. In some embodiments, the plurality of micro-lenses 616 may be formed by depositing a micro-lens material on the plurality of color filters 614a-614b (e.g., via CVD, PVD, ALD, sputtering, a spin-on process, etc.). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed, and baked to form a rounding shape. The plurality of micro-lenses 616 are then formed by selectively etching the micro-lens material according to the micro-lens template.

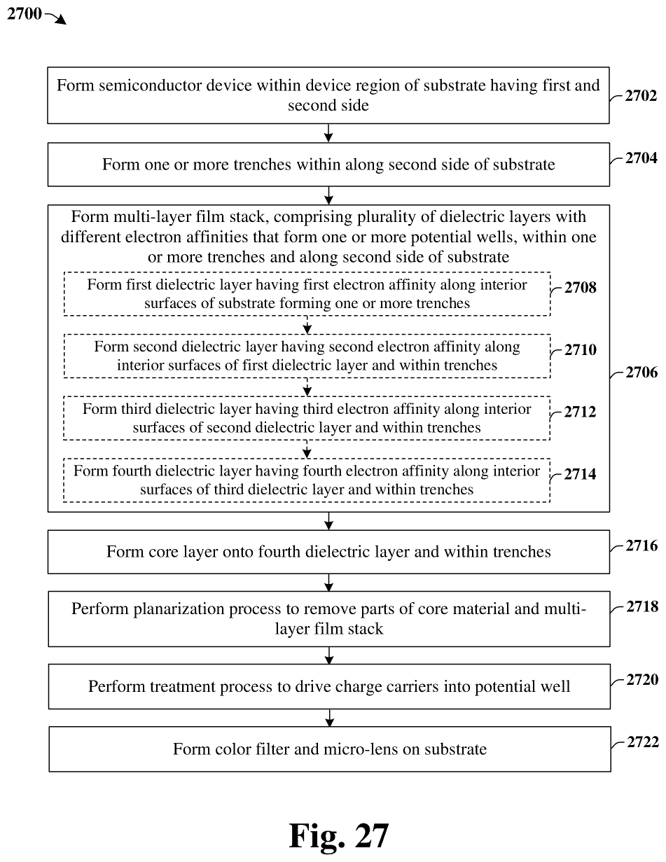

FIG. 27 illustrates a flow diagram of some embodiments of a method 2700 of forming an integrated chip comprising a trench isolation structure having a multi-layer film stack that forms a potential well configured to trap charge carriers.

While method 2700 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2702, one or more semiconductor devices are formed within a device region of a substrate. In some embodiments, the one or more semiconductor device may comprise an image sensing element (e.g., a photodiode), a transistor device, and/or the like. FIGS. 13 and/or 14 illustrate cross-sectional views, 1300 and/or 1400, of some embodiments corresponding to act 2702.

At act 2704, one or more trenches are formed within the substrate. FIG. 16 illustrates a cross-sectional view 1600 of some embodiments corresponding to act 2704.

At act 2706, a multi-layer film stack is formed within the one or more trenches. The multi-layer film stack includes a plurality of films with different electron affinities. The different electron affinities form one or more potential wells within the multi-layer film stack. In some embodiments, the multi-layer film stack may be formed according to acts 2708-2714.

At act 2708, a first dielectric layer having a first electron affinity is formed along interior surfaces of the substrate and within the one or more trenches. FIG. 17 illustrates a cross-sectional view 1700 of some embodiments corresponding to act 2708.

At act 2710, a second dielectric layer having a second electron affinity is formed along interior surfaces of the first dielectric layer and within the one or more trenches. FIG. 18 illustrates a cross-sectional view 1800 of some embodiments corresponding to act 2710.

At act 2712, a third dielectric layer having a third electron affinity is formed along interior surfaces of the second dielectric layer and within the one or more trenches. FIG. 19 illustrates a cross-sectional view 1900 of some embodiments corresponding to act 2712.

At act 2714, a fourth dielectric layer having a fourth electron affinity is formed along interior surfaces of the third dielectric layer and within the one or more trenches. FIG. 20 illustrates a cross-sectional view 2000 of some embodiments corresponding to act 2714.

At act 2716, a core material is formed along interior surfaces of the fourth dielectric film and within the one or more trenches. FIG. 21 illustrates a cross-sectional view 2100 of some embodiments corresponding to act 2716.

At act 2718, a planarization process is performed to remove parts of the core material and the multi-layer film stack. FIG. 22 illustrates a cross-sectional view 2200 of some embodiments corresponding to act 2718.

At act 2720, one or more treatments are performed to drive charge carriers (e.g., electrons) into the one or more potential wells within the multi-layer film stack. In some embodiment, the one or more treatments may comprise one or more of a thermal process, the application of a bias voltage, and/or the like. FIG. 23A illustrates a cross-sectional view 2300 of some embodiments corresponding to act 2720. FIG. 23B illustrates a cross-sectional view 2304 of some alternative embodiments corresponding to act 2720.

At act 2722, a plurality of color filters and micro-lenses are formed on the substrate. FIGS. 24-26 illustrate cross-sectional views 2300-2500 of some embodiments corresponding to act 2722.

Accordingly, in some embodiments, the present disclosure relates to an integrated chip comprising a trench isolation structure having a disclosed multi-layer film stack that forms one or more potential wells configured to trap charge carriers (e.g., electrons).

In some embodiments, the present disclosure relates to an integrated chip. The integrated chip includes a substrate having a device region with one or more semiconductor devices, the substrate having one or more interior surfaces that form one or more trenches within the substrate along opposing sides of the device region; a multi-layer film stack disposed along the one or more interior surfaces of the substrate; a core material arranged within the one or more trenches and surrounded by the multi-layer film stack; and the multi-layer film stack including a plurality of dielectric materials respectively having different electron affinities, the plurality of dielectric materials being arranged to form one or more potential wells within the multi-layer film stack. In some embodiments, the device region includes an image sensing element configured to convert radiation to an electrical signal. In some embodiments, the multi-layer film stack includes a first dielectric material having a first electron affinity a second dielectric material having a second electron affinity that is larger than the first electron affinity; a third dielectric material having a third electron affinity that is smaller than the second electron affinity; and a fourth dielectric material having a fourth electron affinity. In some embodiments, the fourth dielectric material has a greater oxygen density than the third dielectric material. In some embodiments, a conductive energy band of the multi-layer film stack is symmetric. In some embodiments, a conductive energy band of the multi-layer film stack is asymmetric. In some embodiments, the one or more potential wells include two potential wells. In some embodiments, the multi-layer film stack has a thickness that is in a range of between approximately 50 nanometers and approximately 100 nanometers.

In other embodiments, the present disclosure relates to an integrated chip. The integrated chip includes a substrate having a pixel region with an image sensing element configured to convert radiation into an electrical signal; one or more trench isolation structures disposed within the substrate along opposing sides of the pixel region, the one or more trench isolation structures including a first dielectric material having a first electron affinity; a second dielectric material disposed on the first dielectric material and having a second electron affinity; a third dielectric material disposed on the second dielectric material and having a third electron affinity; a fourth dielectric material disposed on the third dielectric material and having a fourth electron affinity; and a core material arranged on the fourth dielectric material; the second electron affinity being larger than both the first electron affinity and the third electron affinity. In some embodiments, a difference between the first electron affinity and the second electron affinity is greater than 0.0.01 electron volts (cV). In some embodiments, the one or more trench isolation structures further include a fifth dielectric material disposed on the fourth dielectric material, the fifth dielectric material having a fifth electron affinity that is smaller than the fourth electron affinity. In some embodiments, the integrated chip further includes a dielectric structure arranged on the substrate and contacting topmost surfaces of the first dielectric material, the second dielectric material, the third dielectric material, the fourth dielectric material, and the core material. In some embodiments, the integrated chip further includes one or more conductive routing layers within the dielectric structure, the one or more conductive routing layers contacting the core material, the core material being a conductive material.

In yet other embodiments, the present disclosure relates to a method of forming an integrated chip. The method includes forming a semiconductor device within a substrate having a first side and a second side; etching the second side of the substrate to form one or more trenches within the substrate along opposing sides of the semiconductor device; forming a multi-layer film stack within the one or more trenches and along the second side of the substrate, the multi-layer film stack having a plurality of dielectric materials with different electron affinities that form one or more potential wells; and forming a core material within the one or more trenches and on the multi-layer film stack. In some embodiments, forming the multi-layer film stack includes forming a first dielectric layer having a first electron affinity; forming a second dielectric layer having a second electron affinity that is larger than the first electron affinity; forming a third dielectric layer having a third electron affinity that is smaller than the second electron affinity; and forming a fourth dielectric layer having a fourth electron affinity. In some embodiments, the method further includes performing a planarization process to remove parts of the first dielectric layer, the second dielectric layer, the third dielectric layer, the fourth dielectric layer, and the core material from along the second side of the substrate. In some embodiments, the one or more potential wells include a potential well at a location corresponding to the second dielectric layer and surrounded by energy barriers corresponding to the first dielectric layer and the third dielectric layer. In some embodiments, the fourth dielectric layer has a greater oxygen density than the third dielectric layer. In some embodiments, the method further includes performing a thermal process to cause charge carriers to tunnel through one or more energy barriers and into the one or more potential wells. In some embodiments, the method further includes applying a bias voltage across the multi-layer film stack to cause charge carries to tunnel through one or more energy barriers and into the one or more potential wells.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a substrate having a device region comprising one or more semiconductor devices, wherein the substrate has one or more interior surfaces that form one or more trenches within the substrate along opposing sides of the device region;
a multi-layer film stack disposed along the one or more interior surfaces of the substrate;
a core material arranged within the one or more trenches and surrounded by the multi-layer film stack; and
wherein the multi-layer film stack comprises a plurality of dielectric materials respectively having different electron affinities, the plurality of dielectric materials being arranged to form one or more potential wells within the multi-layer film stack.

2. The integrated chip of claim 1, wherein the device region comprises an image sensing element configured to convert radiation to an electrical signal.

3. The integrated chip of claim 1, wherein the multi-layer film stack comprises:
a first dielectric material having a first electron affinity;
a second dielectric material having a second electron affinity that is larger than the first electron affinity;
a third dielectric material having a third electron affinity that is smaller than the second electron affinity; and
a fourth dielectric material having a fourth electron affinity.

4. The integrated chip of claim 3, wherein the fourth dielectric material has a greater oxygen density than the third dielectric material.

5. The integrated chip of claim 1, wherein a conductive energy band of the multi-layer film stack is symmetric.

6. The integrated chip of claim 1, wherein a conductive energy band of the multi-layer film stack is asymmetric.

7. The integrated chip of claim 1, wherein the one or more potential wells include two potential wells.

8. The integrated chip of claim 1, wherein the multi-layer film stack has a thickness that is in a range of between approximately 50 nanometers and approximately 100 nanometers.

9. An integrated chip, comprising:
a substrate having a pixel region comprising an image sensing element configured to convert radiation into an electrical signal;
one or more trench isolation structures disposed within the substrate along opposing sides of the pixel region, wherein the one or more trench isolation structures comprise:
a first dielectric material having a first electron affinity;
a second dielectric material disposed on the first dielectric material and having a second electron affinity;
a third dielectric material disposed on the second dielectric material and having a third electron affinity;
a fourth dielectric material disposed on the third dielectric material and having a fourth electron affinity; and
a core material arranged on the fourth dielectric material; and
wherein the second electron affinity is larger than both the first electron affinity and the third electron affinity.

10. The integrated chip of claim 9, wherein a difference between the first electron affinity and the second electron affinity is greater than 0.0.01 electron volts (eV).

11. The integrated chip of claim 9, wherein the one or more trench isolation structures further comprise:
a fifth dielectric material disposed on the fourth dielectric material, wherein the fifth dielectric material has a fifth electron affinity that is smaller than the fourth electron affinity.

12. The integrated chip of claim 9, further comprising:
a dielectric structure arranged on the substrate and contacting topmost surfaces of the first dielectric material, the second dielectric material, the third dielectric material, the fourth dielectric material, and the core material.

13. The integrated chip of claim 12, further comprising:
one or more conductive routing layers within the dielectric structure, the one or more conductive routing layers contacting the core material, wherein the core material is a conductive material.

14. A method of forming an integrated chip, comprising:
forming a semiconductor device within a substrate having a first side and a second side;
etching the second side of the substrate to form one or more trenches within the substrate along opposing sides of the semiconductor device;
forming a multi-layer film stack within the one or more trenches and along the second side of the substrate, wherein the multi-layer film stack comprises a plurality of dielectric materials with different electron affinities that form one or more potential wells; and
forming a core material within the one or more trenches and on the multi-layer film stack.

15. The method of claim 14, wherein forming the multi-layer film stack comprises:
forming a first dielectric layer having a first electron affinity;
forming a second dielectric layer having a second electron affinity that is larger than the first electron affinity;
forming a third dielectric layer having a third electron affinity that is smaller than the second electron affinity; and
forming a fourth dielectric layer having a fourth electron affinity.

16. The method of claim 15, further comprising:
performing a planarization process to remove parts of the first dielectric layer, the second dielectric layer, the third dielectric layer, the fourth dielectric layer, and the core material from along the second side of the substrate.

17. The method of claim 15, wherein the one or more potential wells comprise a potential well at a location corresponding to the second dielectric layer and surrounded by energy barriers corresponding to the first dielectric layer and the third dielectric layer.

18. The method of claim 15, wherein the fourth dielectric layer has a greater oxygen density than the third dielectric layer.

19. The method of claim 14, further comprising:
performing a thermal process to cause charge carriers to tunnel through one or more energy barriers and into the one or more potential wells.

20. The method of claim 14, further comprising:
applying a bias voltage across the multi-layer film stack to cause charge carries to tunnel through one or more energy barriers and into the one or more potential wells.
